(19) United States
(12) Patent Application Publication
(10) Pub. No.: US 2005/0212010 A1
(43) Pub. Date: Sep. 29, 2005

(54) Micro-protruding structure

(76) Inventor: Masatsugu Shigeno, Chiba-shi (JP)

Correspondence Address: BRUCE L. ADAMS, ESQ., 31ST FLOOR, 50 BROADWAY, NEW YORK, NY, 10004, US

(21) Appl. No.: 11/066,086

(22) Filed: Feb. 25, 2005

(30) Foreign Application Priority Data
Mar. 25, 2004 (JP) 2004-088470

(51) Int. Cl. H01L 29/45

(52) U.S. Cl. 257/144

(57) ABSTRACT

A micro-protruding structure which has a high positional precision and an angular (directional) precision, which is made of a linear material having a large aspect ratio, and which is provided for an analyzer, a display device, a machining device, a measuring device and an observation device. The micro-protruding structure is fabricated by growing a linear material of a carbon nano-tube from the bottom of the hole structure perforated by a focused ion beam. This permits a direction from the bottom of the hole structure to the opening to become nearly in alignment with the direction of the linear material that protrudes from the hole structure.

### BACKGROUND OF THE INVENTION

1. Field of the Invention

This invention relates to a micro-protruding structure provided for an analyzer, a display device, a machining device, a measuring device and an observation device. More particularly, the invention relates to a micro-protruding structure provided for a probe portion of a scanning probe microscope, for an electrode portion for emitting electrons, for a probe portion of a micro-chemical chip, for a probe portion for detecting a micro-current of biological tissues, and for a probe portion used for a high-density recording/reproducing apparatus.

2. Description of the Related Art

In order to observe fine structures on the surfaces of samples on a nanometer scale, the scanning probe microscope has heretofore been using a probe portion having a micro-protruding structure at an end thereof for scanning the surfaces of the samples and is provided with a sharp probe having an end portion of a diameter of not larger than 10 μm. In order to observe the ruggedness on the surfaces of the samples maintaining a high resolution, there has, in recent years, been placed in the market a probe having an end which is as fine as 0.05 μm or smaller and, further, being provided with a linear micro-protruding structure.

The micro-protruding structure for the scanning probe microscope must meet such characteristics as a sharp end, a high positional precision, a high angular (directional) precision at the end portion, and a large aspect ratio relative to the thickness of the end portion. To meet such characteristics, the micro-protruding structure for the scanning probe microscope has a micro-cantilever provided at an end portion thereof, the micro-cantilever being usually fabricated by machining a semiconductor wafer by utilizing the photolithography technology.

In general, the micro-protruding structure has such concrete shapes as a square conical shape or a triangular conical shape having a side on the bottom surface of about 10 μm, or a mountain shape like a cone having a diameter on the bottom surface of about 10 μ. In recent years, there has been produced a micro-protruding structure having a linear material of an aspect ratio of not smaller than 10 and a length of 100 to 5000 μm provided at an angle of inclination of not larger than ±20 degrees relative to the mounting surface.

The conventional micro-protruding structures have heretofore been fabricated generally by the following methods.
1. A method of constituting a micro-protruding structure from a semiconductor wafer by utilizing a photolithography technology and, further, forming an end portion therefrom.
2. A method of re-constituting a micro-protruding structure by attaching, by using a manipulator, a linear material on an end portion of the micro-protruding structure fabricated by the method 1 above.
3. A method of constituting a micro-protruding structure by growing a linear material by dispersing a catalyst on an end portion of the micro-protruding structure fabricated by the method 1 above.

However, the above fabrication methods are not capable of fully satisfying the characteristics required for the micro-protruding structure.

Concretely speaking, when the micro-protruding structure is to be fabricated from the semiconductor wafer by utilizing the photolithography technology, there obtained a good positional precision and good angle. However, since the end portion of the micro-protruding structure is formed by the deposition based on the etching technology or evaporation, the end portion assumes such a shape as a square cone, a triangular cone or a cone having a thick root, and the aspect ratio is as small as about 1 to about 5 (see, for example, a patent document 1).

When a linear material is mounted on the mother member on the lever by using a manipulator in the scanning electron microscope to constitute a micro-protruding structure, the aspect ratio can be increased to be not smaller than 10 owing to the use of the linear material. Besides, a favorable positional precision is accomplished at the end portion since the linear material is mounted while making sure the mounting position by using the scanning electron microscope. However, since the observation is from one direction only, the direction in which the linear material protrudes is not determined, and the angular precision is poor (see, for example, a patent document 2).

When the micro-protruding structure is to be constituted by dispersing the catalyst on the mother member on the lever to grow the linear material, the positional precision is poor since it is difficult to mount the catalyst of about several tens to several namometers on a desired position maintaining a high positional precision. Besides, since the direction of growth is not definite, the micro-protruding structure cannot be constituted by the linear material that is controlled at a desired angle (direction).
Patent document 1: Japanese Patent No. 3384116
   (paragraphs 0005-0006, FIG. 6)
Patent document 2: JP-A 2000-227435
   (paragraphs 0004-0010, FIGS. 15, 19, 20, 21, 22)

As described above, the conventional protruding structure is not capable of satisfying all of the positional precision at a position where the linear material of the end portion is provided, angular (directional) precision, thickness and aspect ratio.

When the micro-protruding structure is to be fabricated by mounting the linear material by using a manipulator in the scanning electron microscope, the mounting angle can be confirmed from one direction only. It is therefore difficult to so fabricate the micro-protruding structure as to accomplish a desired angle. Besides, since each micro-protruding structure is fabricated by hand by using a manipulator, the productivity is low.

When the micro-protruding structure is to be constituted by using a material for growing the linear material, it is difficult to mount, on a desired position, the material that is to be grown by about several tens to several namometers. Besides, the direction of growth is not definite. It is not, therefore, possible to constitute the micro-protruding structure maintaining a desired positional precision by using the linear material of which the direction is controlled.

### SUMMARY OF THE INVENTION

In view of the above-mentioned problems, it is an assignment of the present invention to provide a micro-protruding structure which has a high positional precision and an angular (directional) precision, which is made of a linear material having a large aspect ratio, and which is provided for an analyzer, a display device, a machining device, a measuring device and an observation device.

In order to solve the above assignment, the present invention provides a micro-protruding structure provided for any one of an analyzer, a display device, a machining device, a measuring device or an observation device, the micro-protruding structure having at least one or more fine hole structures and at least one or more fine linear materials protruding from the hole structures, the direction from the bottoms of the hole structures to the openings thereof being nearly in alignment with the direction of the linear materials.

In the invention, further, the analyzer is a scanning probe microscope, and the micro-protruding structure is provided on a probe portion of the scanning probe microscope.

In the invention, further, the linear material is a carbon nano-tube.

In the invention, further, the hole structures are holes perforated by an ion beam.

In the invention, further, the linear materials are formed by being grown by using a catalyst provided in the hole structures.

The micro-protruding structure of the invention is provided for an analyzer, a display device, a machining device, a measuring device or an observation device. The micro-protruding structure has at least one or more fine hole structures formed in the surface thereof and at least one or more fine linear materials protruding from the surface thereof, the direction from the bottoms of the hole structures to the openings being nearly in alignment with the direction of at least one or more linear materials. It is, therefore, allowed to conduct the analysis maintaining a high resolution, to produce the display at a low voltage yet maintaining a high brightness, and to conduct the machining, measurement and observation maintaining a high resolution and precision. These effects will now be described below in detail.

The linear material of the micro-protruding structure is used as a probe of the scanning probe microscope. To precisely bring the linear material to a position of measurement, the linear material must have been provided at the end of the probe portion maintaining a high positional precision. To observe a sample which is conspicuously rugged, it is necessary that the micro-protruding structure having a high aspect ratio must have been provided perpendicularly to the surface of the sample. By providing the micro-protruding structure of the present invention, it becomes possible to properly control the position for mounting the linear material having a high aspect ratio and the direction thereof (to so constitute that the end of the probe portion is perpendicular to the sample surface).

The micro-protruding structure having hole structures of a small size and provided with fine linear materials, becomes small in size, i.e., of the order of microns or smaller. It is, therefore, made possible to easily realize the micro-protruding structure for a scanning probe microscope that is to be used in tiny regions.

By using carbon nano-tubes or metal whiskers as the linear materials, the volume effect at the end decreases, the shape is measured maintaining an improved resolution, physical properties are measured maintaining an improved resolution, and the shape at the end of the probe is deteriorated less as compared to those of the probe (micro-protruding structure having a small aspect ratio obtained by machining a semiconductor wafer relying upon the photolithography technology) used in the currently employed scanning probe microscopes.

### BRIEF DESCRIPTION OF THE DRAWINGS

FIG. 1 is a view schematically illustrating the constitution of a micro-protruding structure according to a first embodiment of the invention provided on a cantilever of a scanning probe microscope;

FIG. 2 is a view schematically illustrating the micro-protruding structure according to a second embodiment of the invention;

FIG. 3 is a view schematically illustrating the micro-protruding structure according to a third embodiment of the invention; and

FIG. 4 is a sectional view of the micro-protruding structure illustrated in FIG. 3.

### DESCRIPTION OF THE PREFERRED EMBODIMENTS

Embodiments of the invention will now be described in detail with reference to the drawings.

### Embodiment 1

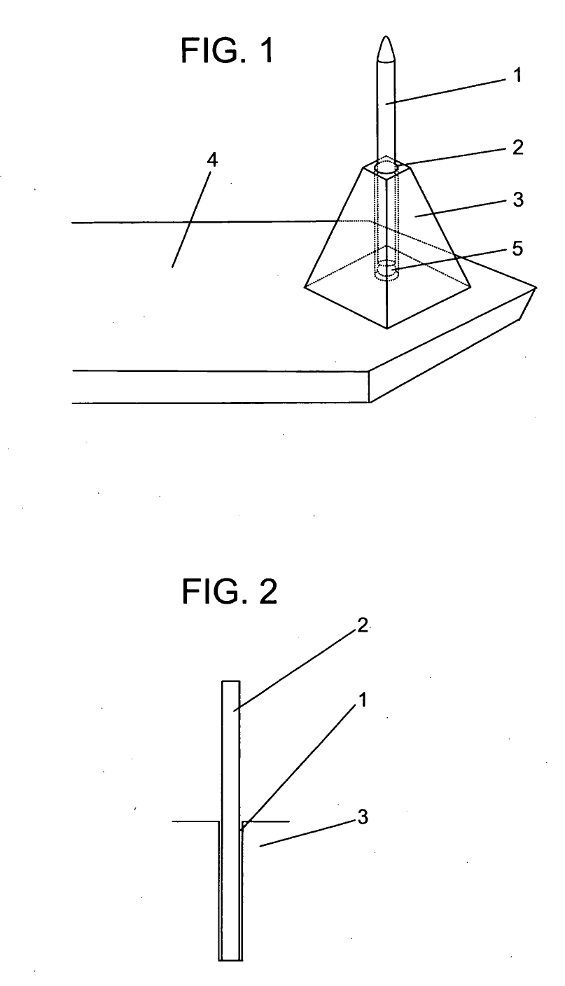

FIG. 1 is a view schematically illustrating the constitution of a micro-protruding structure according to a first embodiment of the invention provided on a cantilever of a scanning probe microscope. In FIG. 1, reference numeral 4 denotes a cantilever (cantilevered beam-type leaf spring) of a scanning probe microscope. At an end of the cantilever 4, there is formed a mother member 3 of a probe portion of the shape of a square truncated cone having a bottom side of about 10 μm. A fine hole structure 1 of a diameter of several tens of nanometers is formed in the central portion of the mother member 3 of the probe portion reaching from the upper surface to the bottom surface thereof nearly at right angles with the surface of the mother member 3 of the probe portion of the cantilever 4. A fine linear material 2 having an aspect ratio of not smaller than 10 is provided in the hole structure 1 so as to protrude outward from the bottom surface of the hole structure 1. The angular direction from the bottom surface of the hole structure 1 to the opening thereof is nearly in alignment with the angular direction of a portion where the linear material 2 is protruding from the hole structure 1.

Next, described below is a method of fabricating the micro-protruding structure (probe) constituted by the hole structure 1, linear material 2 and mother member 3 of the probe portion. First, the mother member 3 of the probe portion is formed by using a semiconductor wafer relying on the photolithography technology at the end of the cantilever 4 made of, for example, silicon. Next, the central portion at the end of the mother member 3 of the probe portion is irradiated with a focused ion beam from a direction nearly at right angles with the surface forming the mother member 3 of the probe portion of the cantilever 4 thereby to perforate the hole. The depth of the hole perforated by the focused ion beam is until the surface of the mother member 3 of the probe portion of the cantilever 4 is reached. Upon perforating the hole using the focused ion beam, there is fabricated a fine hole structure 1 having a good positional precision and a good directional precision.

Next, by using a manipulator in the scanning electron microscope, a catalyst 5 for forming a carbon nano-tube is introduced into the bottom of the fine hole structure 1. By irradiating the catalyst 5 with a high-energy laser beam, a carbon nano-tube is formed along the side wall surface of the hole structure. The carbon nano-tube grows upon continuing the irradiation with the high-energy laser beam. The growing carbon nano-tube reaches the opening of the hole structure 1, while the irradiation with the high-energy laser beam continues. Then, the carbon nano-tube that has grown along the side wall surface of the hole structure 1 continues to grow without changing its direction of growth even after having passed through the opening of the hole structure 1. Irradiation of the high-energy laser beam is discontinued after the carbon nano-tube has grown to a length necessary as a probe for the scanning type probe microscope. Thus, the fine linear material 2 of carbon nano-tube is formed, and there is fabricated a micro-protruded structure in which the direction from the bottom of the hole structure 1 to the opening is nearly in alignment with the direction of the linear material 2.

The thus fabricated micro-protruding structure of the embodiment 1 makes it possible to decrease the volume effect at the end, to improve the resolution for measuring the shapes, to improve the resolution for measuring the physical properties, to improve the limit of measuring the steeply tilted surfaces and to decrease the deterioration of the shape at the end of the probe as compared to those of the micro-protruding structure (micro-protruding structure having a small aspect ratio obtained by machining a semiconductor wafer relying upon the photolithography technology) used for the conventional scanning probe microscopes.

### Embodiment 2

FIG. 2 is a view schematically illustrating the micro-protruding structure according to a second embodiment of the invention. As an electron-emitting electrode, a linear material 2 of carbon nano-tube is inserted in the hole structure 1 provided vertically to the mother member 3 of the substrate. The hole structure 1 can be formed to in alignment with the center axis of the electron lens. The emission of electrons is homogeneously affected by an electric field, and the aberration of the electron beam is suppressed.

### Embodiment 3

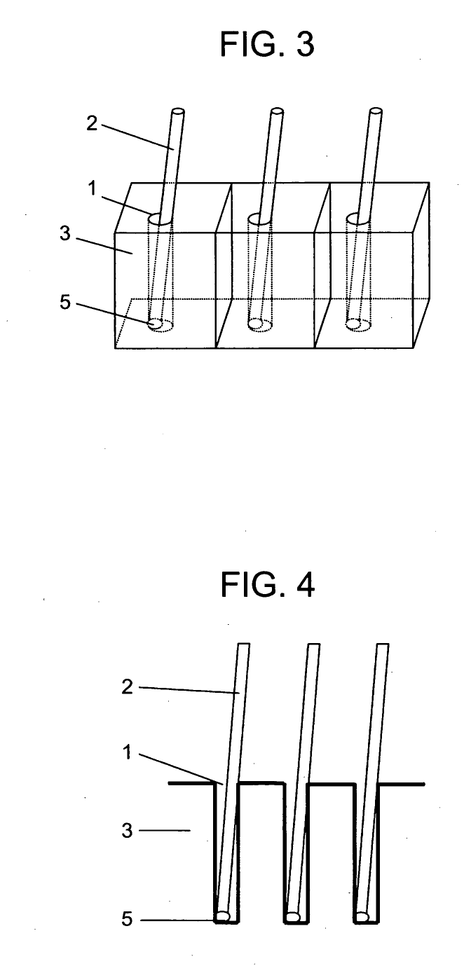

FIG. 3 is a view schematically illustrating the micro-protruding structure according to a third embodiment of the invention. FIG. 4 is a sectional view of the micro-protruding structure illustrated in FIG. 3. As electron-emitting electrodes, there are formed a plurality of micro-protruding structures to emit large amounts of electrons so as to be applied to a display element. By adjusting the density of the hole structures 1, the density of emitting electrodes can be controlled. The direction of the linear materials 2 is determined depending upon the angle of the hole structures, and can be constituted to be perpendicular to the electric field to draw out the electron-emitting efficiency to a maximum degree. The catalysts 5 are provided on the bottom surfaces of the hole structures 1, and the linear materials 2 are grown to provide the structure at one time utilizing many hole structures.

### Description of Reference Numerals

1-hole structures
2-linear materials
3-mother member of probe portion
4-cantilever (leaf spring)
5-catalyst

1. A micro-protruding structure provided for any one of an analyzer, a display device, a machining device, a measuring device or an observation device, the micro-protruding structure having at least one or more fine hole structures and at least one or more fine linear materials protruding from the hole structures, the direction from the bottoms of the hole structures to the openings thereof being nearly in alignment with the direction of the linear materials.

2. A micro-protruding structure according to claim 1, wherein said analyzer is a scanning probe microscope, and said micro-protruding structure is provided on a probe portion of the scanning probe microscope.

3. A micro-protruding structure according to claim 1, wherein said linear material is a carbon nano-tube.

4. A micro-protruding structure according to claim 1, wherein said hole structures are holes perforated by an ion beam.

5. A micro-protruding structure according to claim 1, wherein said linear materials are formed by being grown by using a catalyst provided in the hole structures.
